(19) United States
(12) Patent Application Publication
(10) Pub. No.: US 2024/0274456 A1
(43) Pub. Date: Aug. 15, 2024

(54) SUBSTRATE PLANARIZATION DEVICE, DEPOSITION SYSTEM INCLUDING THE SAME, AND METHOD OF OPERATING SUBSTRATE PLANARIZATION DEVICE

(71) Applicant: Samsung Display Co., Ltd., Yongin-si (KR)

(72) Inventors: Cheol Rae JO, Yongin-si (KR); Seung Ho MYOUNG, Yongin-si (KR); Yeong Min KIM, Yongin-si (KR); Yong U JEONG, Yongin-si (KR)

(21) Appl. No.: 18/414,773

(22) Filed: Jan. 17, 2024

(30) Foreign Application Priority Data
Feb. 9, 2023 (KR) 10-2023-0017314

(51) Int. Cl. H01L 21/683; H01L 21/02; H01L 21/687

(52) U.S. Cl. CPC H01L 21/6833; H01L 21/02631; H01L 21/68742

(57) ABSTRACT

A substrate planarization device according to embodiments of the present disclosure may include a peripheral coupler including a first electrostatic chuck configured to be attached to a peripheral area of a substrate, and a first elevator configured to raise and lower the first electrostatic chuck in a vertical direction within a first movable range, and a central coupler including a second electrostatic chuck configured to be attached to a central area of the substrate, and a second elevator that is configured to raise and lower the second electrostatic chuck in the vertical direction within a second movable range that is greater than the first movable range. According to the substrate planarization device, a deposition system comprising the same, and a method of operating the substrate planarization device according to embodiments of the present disclosure, the substrate can be planarized.

### CROSS-REFERENCE TO RELATED APPLICATION

The application claims priority to, and the benefit of, Korean Patent Application No. 10-2023-0017314, filed Feb. 9, 2023, which is hereby incorporated by reference for all purposes as if fully set forth herein.

### BACKGROUND

### 1. Field

Embodiments of the present disclosure relate to a substrate planarization device, a deposition system including the same, and a method of operating the substrate planarization device.

### 2. Description of the Related Art

As information technology develops, the importance of a display device as a connection medium between a user and information is being emphasized. In response to this, the use of display devices, such as a liquid crystal display device and an organic light-emitting display device, is increasing.

For example, a display panel constituting the organic light-emitting display device may include a light-emitting element. Such a light-emitting element includes a light-emitting layer containing an organic material. As one method for forming the light-emitting layer on the display panel, a deposition process of depositing a deposition material on a substrate may be applied.

As the size of the substrate introduced into the deposition process increases, a central portion of the substrate may sag due to the weight of the substrate. This increases the suitability for a device for planarizing the substrate.

### SUMMARY

Embodiments of the present disclosure provide a substrate planarization device for planarizing a substrate, a deposition system including the same, and a method of operating the substrate planarization device.

A substrate planarization device according to embodiments of the present disclosure may include a peripheral coupler including a first electrostatic chuck configured to be attached to a peripheral area of a substrate, and a first elevator configured to raise and lower the first electrostatic chuck in a vertical direction within a first movable range, and a central coupler including a second electrostatic chuck configured to be attached to a central area of the substrate, and a second elevator that is configured to raise and lower the second electrostatic chuck in the vertical direction within a second movable range that is greater than the first movable range.

The first electrostatic chuck and the second electrostatic chuck may be configured to be individually lowered.

A lowered distance of the second electrostatic chuck may be greater than a lowered distance of the first electrostatic chuck.

The first electrostatic chuck may at least partially surround the second electrostatic chuck.

The peripheral coupler may include a first peripheral coupler on one side of the central coupler, and a second peripheral coupler on another side of the central coupler, wherein the first peripheral coupler includes the first electrostatic chuck and the first elevator, and wherein the second peripheral coupler includes another first electrostatic chuck and another first elevator.

The first peripheral coupler and the second peripheral coupler may be spaced apart from each other with the central coupler interposed therebetween.

The first electrostatic chuck and the second electrostatic chuck might not overlap each other in the vertical direction.

The first electrostatic chuck and the second electrostatic chuck may be spaced apart from each other.

At least a portion of the first electrostatic chuck and at least a portion of the second electrostatic chuck may overlap each other in the vertical direction.

The first electrostatic chuck may include a first protruding portion protruding toward the second electrostatic chuck, wherein the second electrostatic chuck includes a second protruding portion protruding toward the first electrostatic chuck, wherein the first electrostatic chuck includes a first recessed portion corresponding to the second protruding portion, and wherein the second electrostatic chuck includes a second recessed portion corresponding to the first protruding portion.

The first protruding portion may be on the first recessed portion, wherein the second recessed portion is on the second protruding portion.

The first recessed portion may be on the first protruding portion, wherein the second protruding portion is on the second recessed portion.

A size of the first electrostatic chuck may be less than a size of the second electrostatic chuck.

A deposition system according to embodiments of the present disclosure may include a chamber, a deposition source inside the chamber, and configured to supply a deposition material into the chamber, a support above the deposition source, and configured to support a substrate for receiving the deposition material, and a substrate planarization device including a peripheral coupler configured to apply a magnetic force to a peripheral area of the substrate, and a central coupler configured to apply a magnetic force to a central area of the substrate.

The peripheral coupler may include a first electrostatic chuck attached to the peripheral area of the substrate, and a first elevator configured to raise and lower the first electrostatic chuck in a vertical direction within a first movable range, wherein the central coupler includes a second electrostatic chuck attached to the central area of the substrate, and a second elevator configured to raise and lower the second electrostatic chuck in the vertical direction within a second movable range that is greater than the first movable range.

The deposition system may further include a mask assembly overlapping the substrate planarization device on the deposition source.

A method of operating a substrate planarization device according to embodiments of the present disclosure may include lowering a central coupler to a central area of a substrate, lowering a peripheral coupler to a peripheral area of the substrate, and planarizing the substrate by raising the central coupler by a greater distance than the peripheral coupler.

The raising the central coupler may occur before the lowering the peripheral coupler.

A distance at which the substrate sags in a direction of gravity may be greater than about 0 mm and less than about 7 mm after the raising the central coupler.

In the lowering the central coupler, the central coupler may press the peripheral coupler.

### BRIEF DESCRIPTION OF THE DRAWINGS

The accompanying drawings, which are included to provide a further understanding of the present disclosure, and are incorporated in and constitute a part of this specification, illustrate embodiments of the present disclosure, and, together with the description, serve to explain aspects of the present disclosure.

FIG. 1 is a diagram schematically illustrating a deposition system according to embodiments of the present disclosure.

FIG. 2 is a diagram illustrating a substrate planarization device according to a comparative example.

FIG. 3 is a diagram illustrating a substrate planarization device according to embodiments of the present disclosure.

FIG. 4 is a diagram schematically illustrating areas in which the substrate planarization device contacts a substrate according to embodiments of the present disclosure.

FIG. 5 is a diagram schematically illustrating areas in which the substrate planarization device contacts a substrate according to other embodiments of the present disclosure.

FIG. 6 is a diagram illustrating one or more embodiments of the substrate planarization device of FIG. 3.

FIG. 7 is a diagram illustrating one or more other embodiments of the substrate planarization device of FIG. 3.

FIG. 8 is a diagram illustrating still one or more other embodiments of the substrate planarization device of FIG. 3.

FIGS. 9A to 9E are diagrams for explaining one or more embodiments of a method of operating the substrate planarization device shown in FIGS. 6 and 7.

FIGS. 10A to 10E are diagrams for explaining one or more embodiments of a method of operating the substrate planarization device shown in FIG. 8.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing. That is, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

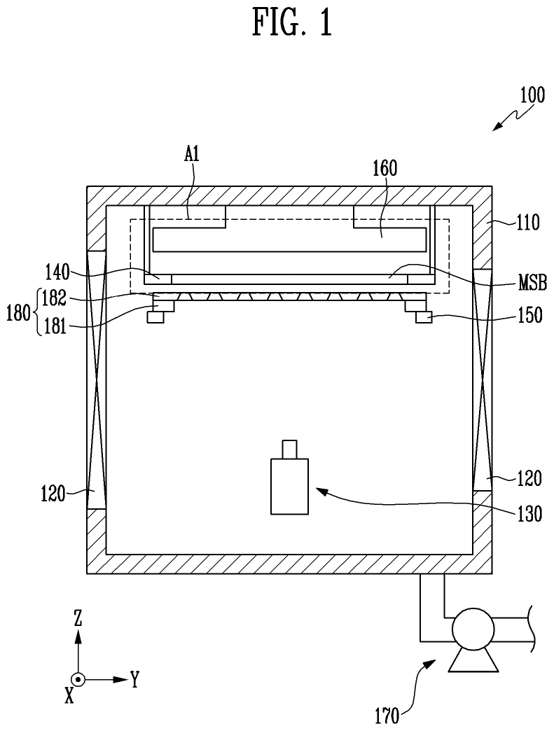

FIG. 1 is a diagram schematically illustrating a deposition system 100 according to embodiments of the present disclosure.

Referring to FIG. 1, the deposition system 100 according to embodiments of the present disclosure may include a chamber 110, a portal (e.g., an opening/closing unit) 120, a deposition source 130, a first support 140, a second support 150, a substrate planarization device 160, a pressure controller 170, and a mask assembly 180.

A space may be formed inside the chamber 110. An internal space of the chamber 110 may be a workspace prepared for a deposition process. An object to be deposited upon may be accommodated (or seated) inside the chamber 110. For example, a substrate MSB (or mother substrate MSB) may be located inside the chamber 110. The substrate MSB may be, for example, a part of a display panel on which pixels are formed. In the following description, it is assumed that the object to be deposited is the substrate MSB, but embodiments of the present disclosure are not limited thereto.

The portal 120 may be located on one side of the chamber 110. The substrate MSB may be inserted into, or taken out of, the internal space of the chamber 110 through the portal 120. The portal 120 may include a valve or the like. The portal 120 may be selectively opened and closed through control.

The deposition source 130 may be located inside the chamber 110. A deposition material may be contained in the deposition source 130. The deposition source 130 may supply the contained deposition material to the internal space of the chamber 110. The deposition material may include a material for forming a pattern layer (e.g., a predetermined pattern layer, or a light-emitting layer) on the substrate MSB. The deposition source 130 may vaporize or sublimate the deposition material by applying energy (e.g., thermal energy, light energy, vibration energy, or the like) to the deposition material. As an example, the deposition source 130 may include a heater therein. As the deposition material inside the deposition source 130 is heated by the operation of the heater, the deposition material may be melted or sublimated. The deposition source 130 can be replaced. When the contained deposition material is exhausted, the deposition source 130 may be replaced with another deposition source.

The first support 140 may support the substrate MSB. For example, the substrate MSB may be seated on the first support 140, and the first support 140 may support the substrate MSB. For example, one surface of the substrate MSB may be adsorbed or attached to the first support 140 so that the first support 140 may support the substrate MSB. For example, the first support 140 may include a clamp for holding the substrate MSB. The first support 140 may adjust the position of the substrate MSB. For example, the first support 140 may include a UVW stage.

The second support 150 may support the mask assembly 180. The second support 150 may be configured the same as, or similar to, the one or more embodiments of the first support 140 described above. The second support 150 may include a frame connected to the inside of the chamber 110. The mask assembly 180 may be seated on the frame of the second support 150, and may be supported by the second support 150.

At least one of the first support 140 and the second support 150 may be elevated (e.g., raised and/or lowered) inside the chamber 110. In this case, a distance between the substrate MSB and the mask assembly 180 may be adjusted by at least one of the first support 140 or the second support 150.

The substrate planarization device 160 may be located inside the chamber 110. The substrate planarization device 160 may move the mask assembly 180 to be close to, or to adhere to, the substrate MSB. The substrate planarization device 160 may include an electromagnet or permanent magnet configured to produce a magnetic force. For example, the substrate planarization device 160 may include an electrostatic chuck, and the magnetic force may be generated by the electrostatic chuck. The substrate planarization device 160 may lift the substrate MSB to a height (e.g., a predetermined height) using the magnetic force to planarize the substrate MSB. Thereby, the distance between the substrate MSB and the mask assembly 180 can be constantly adjusted.

The pressure controller 170 may be connected to the chamber 110 to adjust the pressure inside the chamber 110. The pressure controller 170 may include a pipe connected to the chamber 110, and may include a pump located in the pipe.

The deposition system 100 may further include an image sensor (e.g., a vision unit). The image sensor may be located inside or outside the chamber 110 to capture positions of the mask assembly 180 and the substrate MSB. The image sensor may capture an alignment mark or the like of at least one of the mask assembly 180 or the substrate MSB.

The mask assembly 180 may be located between the substrate MSB and the deposition source 130. The mask assembly 180 may include a mask frame 181 and a mask 182. The mask 182 may be fixed to the mask frame 181 with a tensile force applied in one direction. The mask 182 may include/define one or more openings.

The deposition system 100 may operate as follows.

The portal 120 may be opened in a state in which air pressure inside the chamber 110 is maintained equal to, or similar to, atmospheric pressure by the pressure controller 170. The substrate MSB and the mask assembly 180 may be inserted into the chamber 110 through the opened portal 120. For example, at least one of the substrate MSB or the mask assembly 180 may be moved by a separate robot arm located outside the chamber 110. For example, at least one of the substrate MSB or the mask assembly 180 may be moved by a shuttle or the like that is inserted into, or taken out of, the chamber 110.

The substrate MSB may be located on the first support 140, and the mask assembly 180 may be located on the second support 150. Positions of the mask assembly 180 and the substrate MSB may be adjusted in a precise range based on an image obtained through the image sensor. Thereby, the mask assembly 180 and the substrate MSB can be aligned.

The substrate MSB and the mask assembly 180 may be adjacent to each other, and the mask assembly 180 and the substrate MSB may be brought into close contact with each other by the substrate planarization device 160.

The deposition material may be discharged from the deposition source 130. The discharged deposition material may pass through the opening provided in the mask 182 of the mask assembly 180, and may be deposited on the substrate MSB. For example, the deposition material deposited on the substrate MSB may form an organic layer, such as a light-emitting layer on the substrate MSB.

When the above operations are completed, the substrate MSB may be transported out of the chamber 110, or may be moved to another place inside the chamber 110, and another layer may be further formed on the substrate MSB.

Meanwhile, as the size of the substrate MSB increases, the central portion of the substrate MSB may sag due to gravity, and to a degree that is greater than that of the edge portion of the substrate MSB. Because the deposition source 130 is located under (or below) the substrate MSB, it may be difficult to locate a separate support structure under the substrate MSB. When the central portion of the substrate MSB sages due to the influence of gravity, the central portion of the substrate MSB may be closer to the mask assembly 180, and the edge portion of the substrate MSB may be further away from the mask assembly 180. As a result, a problem in that the deposition material is not uniformly deposited on the substrate MSB may occur. A method to solve this problem may be required.

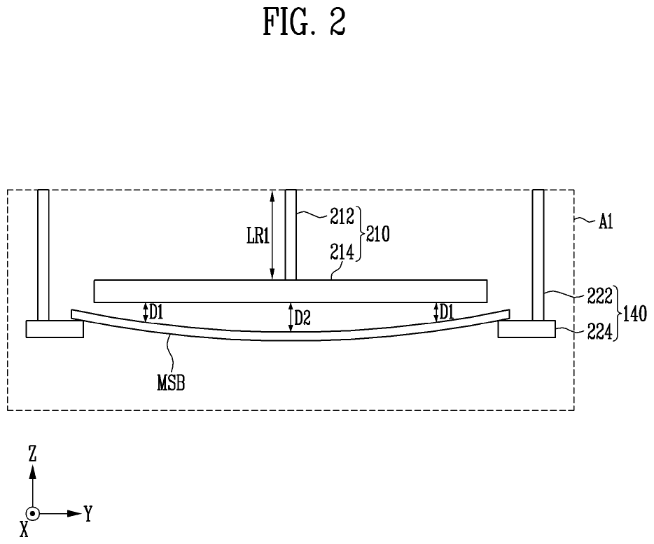

FIG. 2 is a diagram illustrating a substrate planarization device 210 according to a comparative example.

FIG. 2 is a diagram showing the dotted line area Al shown in FIG. 1 in more detail. Referring to FIG. 2, the substrate planarization device 210 according to the comparative example may include an electrostatic chuck 214 and an elevator 212.

The electrostatic chuck 214 may be configured to provide a magnetic force. When the electrostatic chuck 214 provides the magnetic force, the substrate MSB may be adhered to the electrostatic chuck 214, and may be planarized to the shape of the electrostatic chuck 214.

The elevator 212 may be configured to move the electrostatic chuck 214 in a vertical direction (e.g., a direction parallel to a Z axis). The elevator 212 may have a first movable range LR1. The first movable range LR1 may correspond to a distance by which the electrostatic chuck 214 is lowered to a point where the electrostatic chuck 214 contacts an edge of the substrate MSB (or a point where the electrostatic chuck 214 is adjacent to the substrate MSB, so that a peripheral area of the substrate MSB can be lifted by the magnetic force).

Meanwhile, the substrate MSB may be supported by the first support 140. The first support 140 may include a support surface 224 and a connection member 222.

The support surface 224 may be configured to support the substrate MSB. According to one or more embodiments, the support surface 224 may further include a clamp for fixing the substrate MSB. Referring to FIG. 2, the support surface 224 is shown as not overlapping the substrate planarization device 210. However, according to one or more embodiments, at least a portion of the support surface 224 may overlap the substrate planarization device 210.

The connection member 222 may be configured to connect between the support surface 224 and the chamber 110 described above (refer to FIG. 1). According to one or more embodiments, the length of the connection member 222 may be adjusted.

Referring to FIG. 2, as the size of the substrate MSB increases, a distance between the substrate MSB and the electrostatic chuck 214 may vary depending on the position of the substrate MSB. For example, a distance from the peripheral area of the substrate MSB to the electrostatic chuck 214 may be a first distance D1, and a distance from a central area of the substrate MSB to the electrostatic chuck 214 may be a second distance D2. The first distance D1 and the second distance D2 may be different from each other. As an example, the first distance D1 may correspond to a distance at which the peripheral area of the substrate MSB cannot be lifted by the magnetic force. The second distance D2 may correspond to a distance at which the central area of the substrate MSB can be lifted by the magnetic force. As the size of the substrate MSB increases, the second distance D2 may gradually increase. Therefore, it may be difficult to sufficiently planarize the substrate MSB even if the substrate planarization device 210 shown in the comparative example is used. As a result, a distance between the substrate MSB and the mask assembly 180 described above (refer to FIG. 1) may be non-uniform depending on the position within the substrate MSB. As a result, because the deposition material is not uniformly deposited on the substrate MSB, deposition quality may deteriorate.

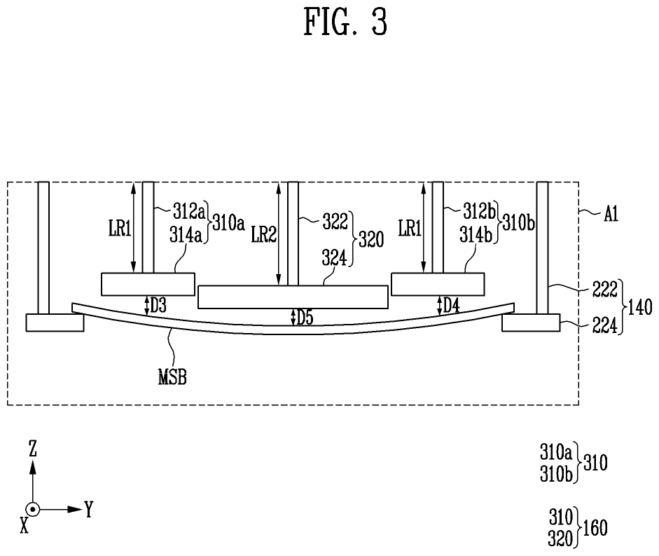

FIG. 3 is a diagram illustrating a substrate planarization device 160 according to embodiments of the present disclosure.

FIG. 3 is a diagram showing the dotted line area Al of FIG. 1 in more detail. Referring to FIG. 3, the substrate planarization device 160 according to embodiments of the present disclosure may include a peripheral coupler 310 and a central coupler 320.

The peripheral coupler 310 may be attached to the substrate MSB at the peripheral area of the substrate MSB. Referring to FIG. 3, the peripheral coupler 310 may include a first peripheral coupler 310a attached to the substrate MSB at the peripheral area of one side of the substrate MSB, and a second peripheral coupler 310b attached to the substrate MSB at the peripheral area of the other side of the substrate MSB. The central area of the substrate MSB may be positioned between the peripheral area of one side of the substrate MSB and the peripheral area of the other side of the substrate MSB. The first peripheral coupler 310a and the second peripheral coupler 310b may be driven independently of each other. According to one or more embodiments, the first peripheral coupler 310a and the second peripheral coupler 310b may be driven simultaneously.

The first peripheral coupler 310a may include a first electrostatic chuck 314a and a first elevator 312a. The first electrostatic chuck 314a may be attached to the peripheral area of one side of the substrate MSB. The first elevator 312a may be configured to move the first electrostatic chuck 314a in the vertical direction (e.g., the direction parallel to the Z axis).

The first peripheral coupler 310a may have the first movable range LR1. A distance between the substrate MSB and the first peripheral coupler 310a may be a third distance D3. The third distance D3 may correspond to a distance at which the peripheral area of the substrate MSB can be lifted by the magnetic force. Thereby, the first peripheral coupler 310a may be attached to the peripheral area of one side of the substrate MSB to lift the substrate MSB.

The second peripheral coupler 310b may include a first electrostatic chuck 314b and a first elevator 312b. The first electrostatic chuck 314b may be attached to the peripheral area of the other side of the substrate MSB. The first elevator 312b may be configured to move the first electrostatic chuck 314b in the vertical direction (e.g., the direction parallel to the Z axis).

The second peripheral coupler 310b may have the first movable range LR1. A distance between the substrate MSB and the second peripheral coupler 310b may be a fourth distance D4. The fourth distance D4 may be the same as the third distance D3.

According to one or more embodiments, the fourth distance D4 may be different from the third distance D3. For example, the first peripheral coupler 310a may be lowered by the third distance D3 from the substrate MSB, and the first peripheral coupler 310a may lift the peripheral area of one side of the substrate MSB. The second peripheral coupler 310b may be lowered by the fourth distance D4 from the substrate MSB, and the second peripheral coupler 310b may lift the peripheral area of the other side of the substrate MSB. In this case, the third distance D3 and the fourth distance D4 may be different from each other.

The fourth distance D4 may correspond to a distance at which the peripheral area of the substrate MSB can be lifted by the magnetic force. Thereby, the second peripheral coupler 310b may be attached to the peripheral area of the other side of the substrate MSB to lift the substrate MSB.

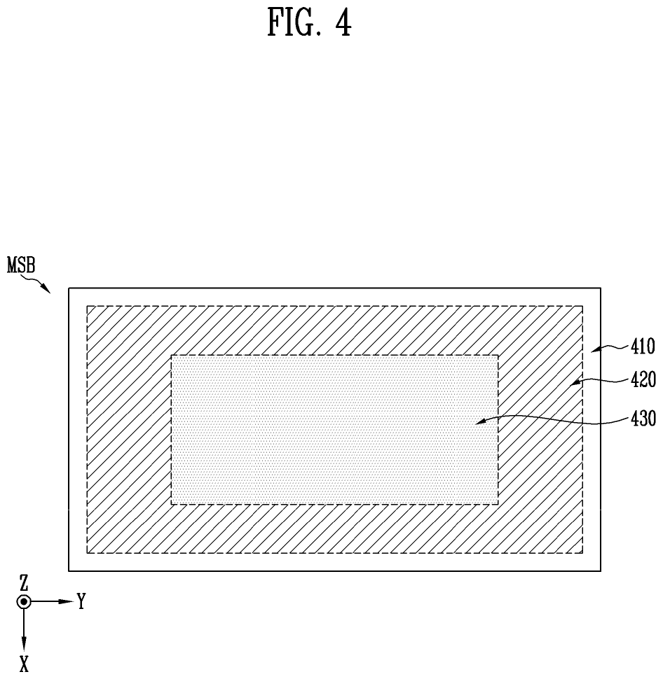

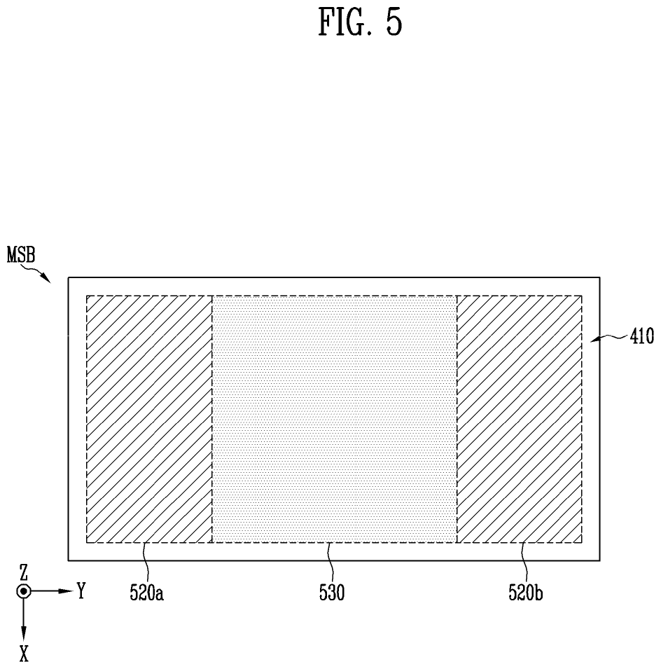

The first electrostatic chuck 314b of the second peripheral coupler 310b may be integrally formed with the first electrostatic chuck 314a of the first peripheral coupler 310a. The above embodiments may be described with respect to the one or more embodiments corresponding to FIG. 4. The first electrostatic chuck 314b of the second peripheral coupler 310b may be formed separately. The above embodiments may be described with respect to the one or more embodiments corresponding to FIG. 5.

The central coupler 320 may include a second electrostatic chuck 324 and a second elevator 322. The second electrostatic chuck 324 may be attached to the central area of one side of the substrate MSB. The second elevator 322 may be configured to move the second electrostatic chuck 324 in the vertical direction (e.g., the direction parallel to the Z axis).

The central coupler 320 may have the second movable range LR2. A distance between the substrate MSB and the central coupler 320 may be a fifth distance D5. The fifth distance D5 may correspond to a distance at which the central area of the substrate MSB can be lifted by the magnetic force. Thereby, the central coupler 320 may be attached to the central area of the substrate MSB to lift the substrate MSB.

The substrate planarization device 160 according to the embodiments of the present disclosure may be attached to the central area of the substrate MSB and the peripheral area of the substrate MSB, respectively. Accordingly, the substrate MSB with a large size can be suitably planarized. As a result, the deposition quality can be improved.

FIG. 4 is a diagram schematically illustrating areas in which the substrate planarization device 160 (refer to FIGS. 1 and 3) contacts a substrate MSB according to embodiments of the present disclosure.

Referring to FIG. 4, the substrate MSB may include a first area 410, a second area 420, and a third area 430.

The first area 410 may be an area where the substrate MSB is supported by the first support 140 described above (refer to FIG. 1). For example, in the first area 410, the substrate MSB may be held by a clamp or the like of the first support 140.

The second area 420 may be an area where the peripheral coupler 310 (refer to FIG. 3) is attached to the substrate MSB. The third area 430 may be an area where the central coupler 320 (refer to FIG. 3) is attached to the substrate MSB. The second area 420 may correspond to the peripheral area of the substrate MSB. The third area 430 may correspond to the central area of the substrate MSB. The second area 420 may include the peripheral area of one side of the substrate MSB and the peripheral area of the other side of the substrate MSB.

The second area 420 may surround the third area 430. The second area 420 and the third area 430 may be adjacent to each other, but a margin (e.g., a predetermined margin) may be provided between the second area 420 and the third area 430.

Shapes of the second area 420 and the third area 430 are shown as rectangles. However, embodiments of the present disclosure are not limited thereto. For example, the shape of the second area 420 may be circular, elliptical, or polygonal. The shape of the third area 430 may be circular, elliptical, or polygonal. The shapes of the second area 420 and the third area 430 may be similar to each other, but embodiments of the present disclosure are not limited thereto.

FIG. 5 is a diagram schematically illustrating areas in which the substrate planarization device 160 (refer to FIGS. 1 and 3) contacts a substrate MSB according to other embodiments of the present disclosure.

Referring to FIG. 5, the substrate MSB may include a first area 410, a fourth area 520a, a fifth area 520b, and a sixth area 530.

The first area 410 may be an area where the substrate MSB is supported by the first support 140 described above (refer to FIG. 1). A description of the first area 410 may be replaced with the corresponding description of FIG. 4.

The fourth area 520a may be an area where the first peripheral coupler 310a (refer to FIG. 3) is attached to the substrate MSB. The fifth area 520b may be an area where the second peripheral coupler 310b (refer to FIG. 3) is attached to the substrate MSB. The sixth area 530 may be an area where the central coupler 320 (refer to FIG. 3) is attached to the substrate MSB. The fourth area 520a and the fifth area 520b may correspond to the peripheral area of the substrate MSB described above. The sixth area 530 may correspond to the central area of the substrate MSB described above.

Referring to FIG. 5, the fourth area 520a and the fifth area 520b may be spaced apart from each other with the sixth area 530 interposed therebetween. The fourth area 520a may correspond to the peripheral area of one side of the substrate MSB described above. The fifth area 520b may correspond to the peripheral area of the other side of the substrate MSB described above. For example, the fourth area 520a and the fifth area 520b may be in a transverse direction (e.g., a width direction of the substrate MSB, or a direction parallel to a Y axis) from the sixth area 530.

The sixth area 530 may be adjacent to the first area 410.

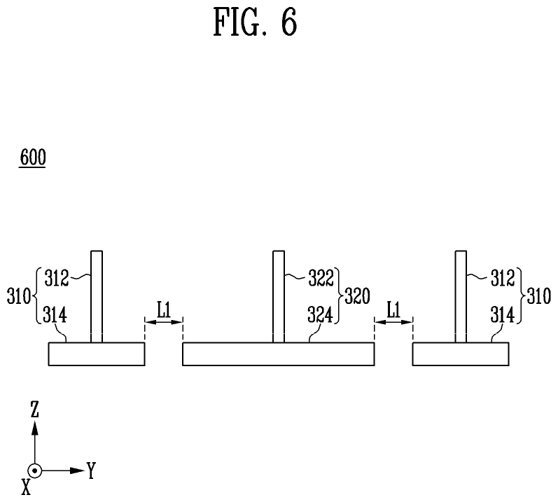

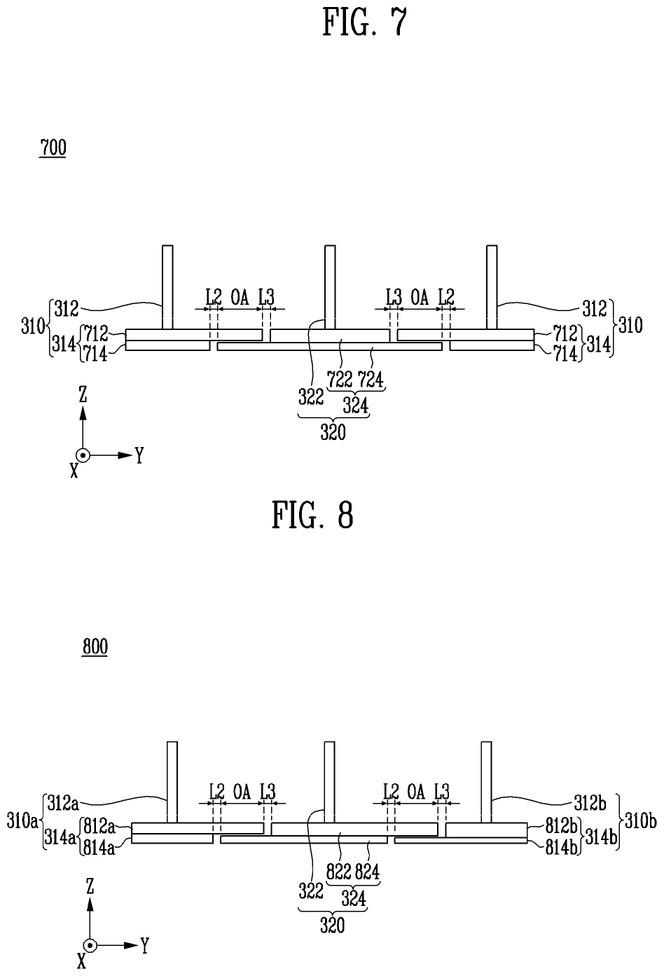

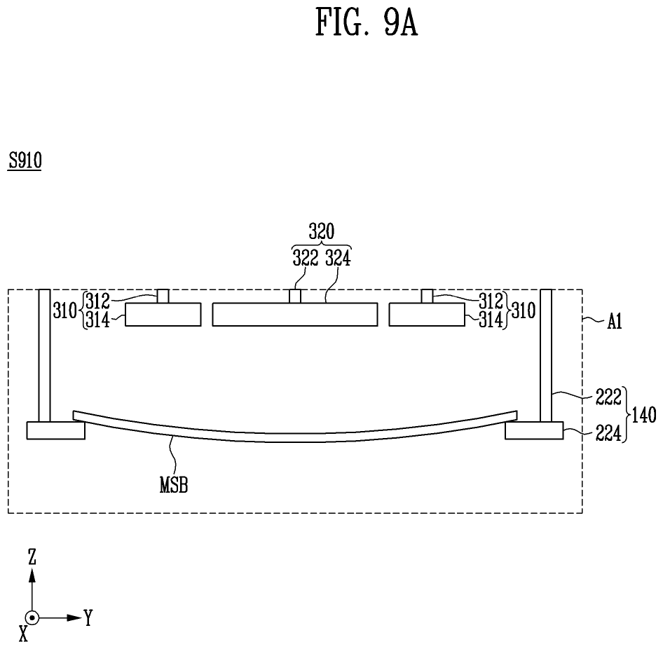

According to one or more embodiments, areas of the fourth area 520a and the fifth area 520b may be the same. A description of the above embodiments may be explained with respect to FIGS. 6 and 7. According to one or more embodiments, the areas of the fourth area 520a and the fifth area 520b may be different from each other. A description of the above embodiments may be explained with respect to FIG. 8.

The area of the fourth area 520a may be less than that of the sixth area 530. The area of the fifth area 520b may be less than that of the sixth area 530.

Shapes of the fourth area 520a, the fifth area 520b, and the sixth area 530 are all shown as rectangles. However, embodiments of the present disclosure are not limited thereto. For example, the shape of the fourth area 520a may be circular, elliptical, or polygonal. The shape of the fifth area 520b may be circular, elliptical, or polygonal. The shape of the sixth area 530 may be circular, elliptical, or polygonal. The shapes of the fourth area 520a and the fifth area 520b may be similar to each other, but the present disclosure is not limited thereto.

FIG. 6 is a diagram illustrating one or more embodiments of the substrate planarization device 160 of FIG. 3.

Referring to FIG. 6, a substrate planarization device 600 is shown. The substrate planarization device 600 may be applied to the substrate planarization device 160 described with reference to FIGS. 1 and 3.

Referring to FIG. 6, the substrate planarization device 600 may include a peripheral coupler 310 and a central coupler 320. The peripheral coupler 310 and the central coupler 320 may be positioned so as not to overlap each other in the vertical direction (e.g., the direction parallel to the Z axis).

The peripheral coupler 310 may include a first elevator 312 and a first electrostatic chuck 314. The central coupler 320 may include a second elevator 322 and a second electrostatic chuck 324.

The peripheral coupler 310 and the central coupler 320 may be spaced apart from each other in the transverse direction (e.g., the direction parallel to the Y axis) and/or in a longitudinal direction (e.g., a direction parallel to an X axis). For example, referring to FIG. 6, the peripheral coupler 310 and the central coupler 320 may be spaced apart from each other with a first separation distance L1 in the transverse direction. The margin (e.g., the predetermined margin) described above (refer to FIG. 4) may be provided by the first separation distance L1.

The first electrostatic chuck 314 and the second electrostatic chuck 324 may have the same thickness. However, embodiments of the present disclosure are not limited thereto, and the thickness of the first electrostatic chuck 314 may be thinner or thicker than the thickness of the second electrostatic chuck 324.

Electrode patterns may be formed on lower surfaces of the first electrostatic chuck 314 and the second electrostatic chuck 324. The electrode pattern formed on the lower surface of the first electrostatic chuck 314 and the electrode pattern formed on the lower surface of the second electrostatic chuck 324 may be the same (or substantially the same). However, embodiments of the present disclosure are not limited thereto. For example, the electrode pattern formed on the lower surface of the first electrostatic chuck 314 may be formed more densely or sparsely than the electrode pattern formed on the lower surface of the second electrostatic chuck 324.

Referring to FIGS. 4 and 6 together, the peripheral coupler 310 may be attached to the second area 420 of the substrate MSB. The central coupler 320 may be attached to the third area 430 of the substrate MSB.

Referring to FIGS. 5 and 6 together, the peripheral coupler 310 may be attached to the fourth area 520a and the fifth area 520b of the substrate MSB. The central coupler 320 may be attached to the sixth area 530 of the substrate MSB. Areas of the fourth area 520a and the fifth area 520b may be the same (or substantially the same).

FIG. 7 is a diagram illustrating one or more other embodiments of the substrate planarization device 160 of FIG. 3.

Referring to FIG. 7, a substrate planarization device 700 is shown. The substrate planarization device 700 may be applied to the substrate planarization device 160 described with reference to FIGS. 1 and 3.

Referring to FIG. 7, the substrate planarization device 700 may include a peripheral coupler 310 and a central coupler 320. At least portions of the peripheral coupler 310 and the central coupler 320 may be positioned to overlap each other in the vertical direction (e.g., the direction parallel to the Z axis).

The peripheral coupler 310 may include a first elevator 312 and a first electrostatic chuck 314. The central coupler 320 may include a second elevator 322 and a second electrostatic chuck 324.

The first electrostatic chuck 314 may include a first protruding portion 712 and a first recessed portion 714. The second electrostatic chuck 324 may include a second recessed portion 722 and a second protruding portion 724.

At least a portion of the first protruding portion 712 and at least a portion of the second protruding portion 724 may overlap each other in the vertical direction. Referring to FIG. 7, in an overlapping area OA, the first protruding portion 712 may overlap the second protruding portion 724 in the vertical direction.

The first recessed portion 714 may be spaced apart from the second protruding portion 724 in the transverse direction (e.g., the direction parallel to the Y axis) and/or the longitudinal direction (e.g., the direction parallel to the X axis). Referring to FIG. 7, the first recessed portion 714 may be spaced apart from the second protruding portion 724 by a second separation distance L2 in the transverse direction. The first recessed portion 714 may be formed to correspond to the second protruding portion 724. The margin (e.g., the predetermined margin) described above (refer to FIG. 4) may be provided by the second separation distance L2.

The second recessed portion 722 may be spaced apart from the first protruding portion 712 in the transverse direction (e.g., the direction parallel to the Y axis) and/or the longitudinal direction (e.g., the direction parallel to the X axis). Referring to FIG. 7, the second recessed portion 722 may be spaced apart from the first protruding portion 712 by a third separation distance L3 in the transverse direction. The second recessed portion 722 may be formed to correspond to the first protruding portion 712.

According to one or more embodiments, the second separation distance L2 and the third separation distance L3 may be the same or different.

A thickness of the first protruding portion 712 may be less than a thickness of the second recessed portion 722. A thickness of the second protruding portion 724 may be less than a thickness of the first recessed portion 714. The sum of the thicknesses of the first protruding portion 712 and the first recessed portion 714 may be equal to (or substantially equal to) the sum of the thicknesses of the second protruding portion 724 and the second recessed portion 722.

Referring to FIG. 7, the first protruding portion 712 is shown to be positioned on the first recessed portion 714, and the second recessed portion 722 is shown to be positioned on the second protruding portion 724, but embodiments of the present disclosure are limited thereto. For example, the first recessed portion 714 may be positioned on the first protruding portion 712, and the second protruding portion 724 may be positioned on the second recessed portion 722.

FIG. 8 is a diagram illustrating still one or more other embodiments of the substrate planarization device 160 of FIG. 3.

Referring to FIG. 8, a substrate planarization device 800 is shown. The substrate planarization device 800 may be applied to the substrate planarization device 160 described with reference to FIGS. 1 and 3.

Referring to FIG. 8, the substrate planarization device 800 may include a first peripheral coupler 310a, a second peripheral coupler 310b, and a central coupler 320. The first peripheral coupler 310a and the second peripheral coupler 310b may constitute the peripheral coupler 310 described above in FIG. 3.

At least portions of the first peripheral coupler 310a and the central coupler 320 may be positioned to overlap each other in the vertical direction (e.g., the direction parallel to the Z axis). At least portions of the second peripheral coupler 310b and the central coupler 320 may be positioned to overlap each other in the vertical direction (e.g., the direction parallel to the Z axis). The first peripheral coupler 310a and the second peripheral coupler 310b may be spaced apart (or separated) from each other.

The first peripheral coupler 310a may include a first elevator 312a and a first electrostatic chuck 314a. The second peripheral coupler 310b may include a first elevator 312b and a first electrostatic chuck 314b. The central coupler 320 may include a second elevator 322 and a second electrostatic chuck 324.

The first electrostatic chuck 314a of the first peripheral coupler 310a may include a first portion 812a and a second portion 814a. The first electrostatic chuck 314b of the second peripheral coupler 310b may include a fifth portion 812b and a sixth portion 814b. The second electrostatic chuck 324 may include a third portion 822 and a fourth portion 824.

At least portions of the first portion 812a of the first peripheral coupler 310a and the fourth portion 824 of the central coupler 820 may overlap in the vertical direction (e.g., the direction parallel to the Z axis). Referring to FIG. 8, in an overlapping area OA, the first portion 812a and the fourth portion 824 may overlap each other in the vertical direction.

The second portion 814a may be spaced apart from the fourth portion 824 in the transverse direction (e.g., the direction parallel to the Y axis) and/or the longitudinal direction (e.g., the direction parallel to the X axis). Referring to FIG. 8, the second portion 814a may be spaced apart from the fourth portion 824 by a second separation distance L2 in the transverse direction. The second portion 814a may be formed to correspond to the fourth portion 824.

The third portion 822 may be spaced apart from the first portion 812a in the transverse direction (e.g., the direction parallel to the Y axis) and/or the longitudinal direction (e.g., the direction parallel to the X axis). Referring to FIG. 8, the third portion 822 may be spaced apart from the first portion 812a by a third separation distance L3 in the transverse direction. The third portion 822 may be formed to correspond to the first portion 812a.

According to one or more embodiments, the second separation distance L2 and the third separation distance L3 may be the same or different.

At least portions of the sixth portion 814b of the second peripheral coupler 310b and the third portion 822 of the central coupler 820 may overlap in the vertical direction (e.g., the direction parallel to the Z axis). Referring to FIG. 8, in an overlapping area OA, the third portion 822 and the sixth portion 814b may overlap in the vertical direction.

The fourth portion 824 may be spaced apart from the sixth portion 814b in the transverse direction (e.g., the direction parallel to the Y axis) and/or the longitudinal direction (e.g., the direction parallel to the X axis). Referring to FIG. 8, the fourth portion 824 may be spaced apart from the sixth portion 814b by the second separation distance L2 in the transverse direction. The fourth portion 824 may be formed to correspond to the sixth portion 814b.

The fifth portion 812b may be spaced apart from the third portion 822 in the transverse direction (e.g., the direction parallel to the Y axis) and/or the longitudinal direction (e.g., the direction parallel to the X axis). Referring to FIG. 8, the fifth portion 812b may be spaced apart from the third portion 822 by the third separation distance L3 in the transverse direction. The fifth portion 812b may be formed to correspond to the third portion 822.

A thickness of the first portion 812a may be less than a thickness of the third portion 822. A thickness of the fourth portion 824 may be less than a thickness of the second portion 814a. The sum of the thicknesses of the first portion 812a and the second portion 814a may be equal to (or substantially equal to) the sum of the thicknesses of the third portion 822 and the fourth portion 824.

The thickness of the third portion 822 may be less than a thickness of the fifth portion 812b. A thickness of the sixth portion 814b may be less than the thickness of the fourth portion 824. The sum of the thicknesses of the fifth portion 812b and the sixth portion 814b may be equal to (or substantially equal to) the sum of the thicknesses of the third portion 822 and the fourth portion 824.

The thickness of the first portion 812a may be less than the thickness of the fifth portion 812b. The thickness of the sixth portion 814b may be less than the thickness of the second portion 814a. The sum of the thicknesses of the first portion 812a and the second portion 814a may be equal to (or substantially equal to) the sum of the thicknesses of the fifth portion 812b and the sixth portion 814b.

Referring to FIG. 8, the first portion 812a is shown to be positioned on the second portion 814a, the third portion 822 is shown to be positioned on the fourth portion 824, and the fifth portion 812b is shown to be positioned on the sixth portion 814b, but embodiments of the present disclosure are not limited thereto. For example, the second portion 814a may be positioned on the first portion 812a, the fourth portion 824 may be positioned on the third portion 822, and the sixth portion 814b may be positioned on the fifth portion 812b.

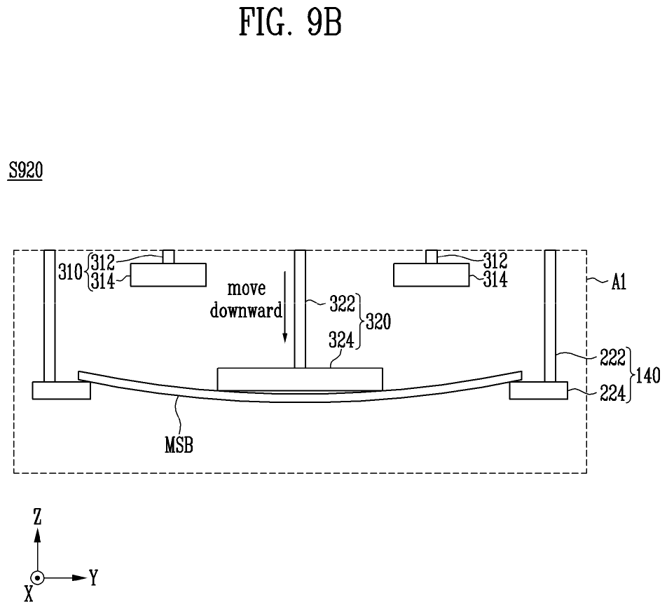

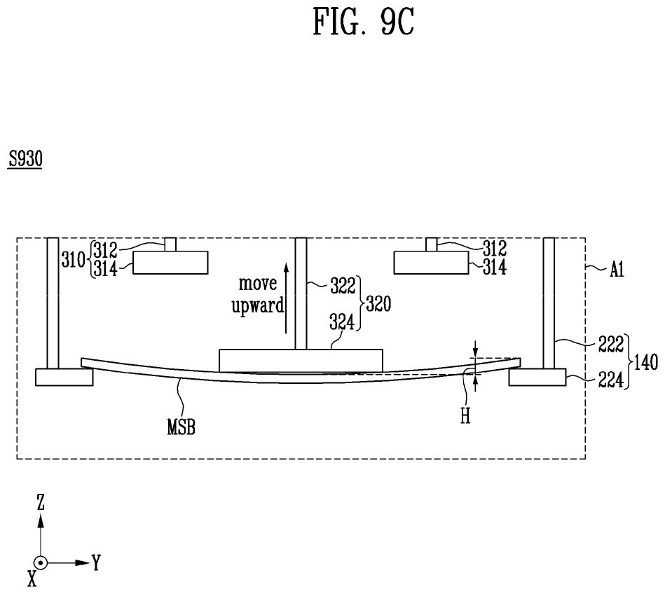

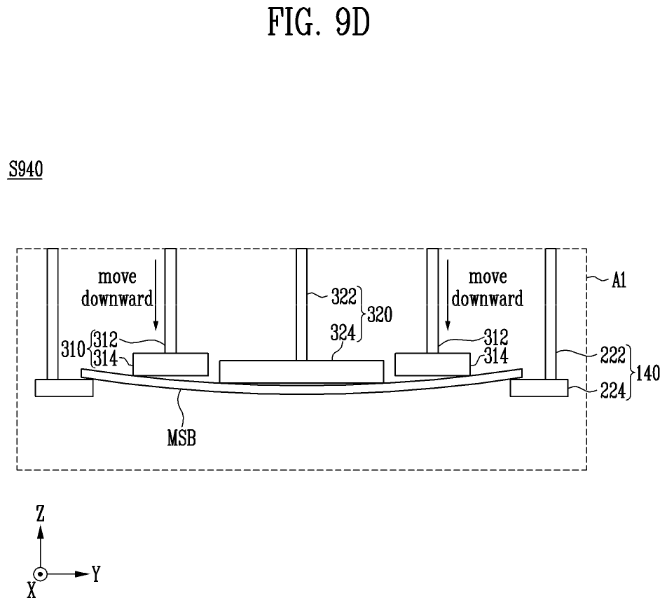

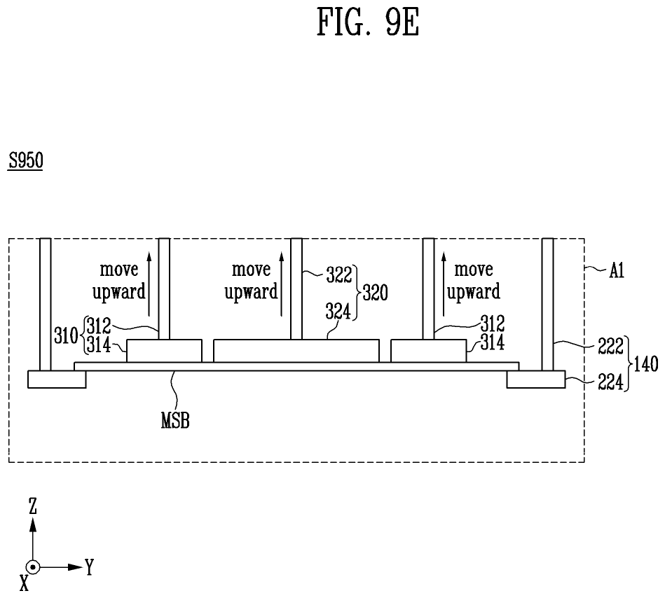

FIGS. 9A to 9E are diagrams for explaining one or more embodiments of a method of operating the substrate planarization device 600 or 700 shown in FIGS. 6 and 7.

Referring to FIGS. 9A to 9E, a method of operating the substrate planarization device according to embodiments of the present disclosure may include seating a substrate (S910), lowering a central coupler (S920), raising the central coupler (S930), lowering a peripheral coupler (S940), and raising the central coupler and the peripheral coupler (S950).

FIG. 9A shows the seating the substrate (S910). In the seating the substrate (S910), the substrate MSB may be seated on the first support 140. The peripheral coupler 310 and the central coupler 320 may be in a raised state.

FIG. 9B shows the lowering the central coupler (S920). In the lowering the central coupler (S920), the central coupler 320 may be lowered. The peripheral coupler 310 may be in a raised state.

FIG. 9C shows the raising the central coupler (S930). In the raising the central coupler (S930), the central coupler 320 may be raised. In the operation (S930), the second electrostatic chuck 324 may generate the magnetic force. The substrate MSB may be attached to the central coupler 320, and may be raised. In the operation (930), the central coupler 320 may be raised until the degree of deflection H of the substrate is less than or equal to a value (e.g., a predetermined value). For example, the degree of deflection H of the substrate may be quantified as a displacement difference in the vertical direction (e.g., the direction parallel to the Z axis) between the peripheral area and the central area of the substrate MSB. As an example, in the operation (S930), the central coupler 320 may be raised until the degree of deflection H of the substrate is about 7 mm or less. Thereby, the substrate MSB may be planarized compared to the previous operation.

FIG. 9D shows the lowering the peripheral coupler (S940). In the lowering the peripheral coupler (S940), the peripheral coupler 310 may be lowered. In the operation (S940), the central coupler 320 may be attached to the substrate MSB. In the operation (S940), the peripheral coupler 310 may be lowered by a distance that is less than the lowered distance of the central coupler 320 in the lowering the central coupler (S920) described above.

FIG. 9E shows the raising the central coupler and the peripheral coupler (S950). In the operation (S950), the first electrostatic chuck 314 and the second electrostatic chuck 324 may generate the magnetic force. The substrate MSB may be attached to the peripheral coupler 310 and the central coupler 320, and may be raised. In the operation (S950), the central coupler 320 may be raised by a greater distance than the peripheral coupler 310. In the operation (S950), the substrate MSB may be planarized. For example, the degree of deflection H of the substrate described above (refer to FIG. 9C) may converge to 0 or a value close thereto.

A deposition material may be deposited on the substrate MSB planarized according to the method of operating the substrate planarization device.

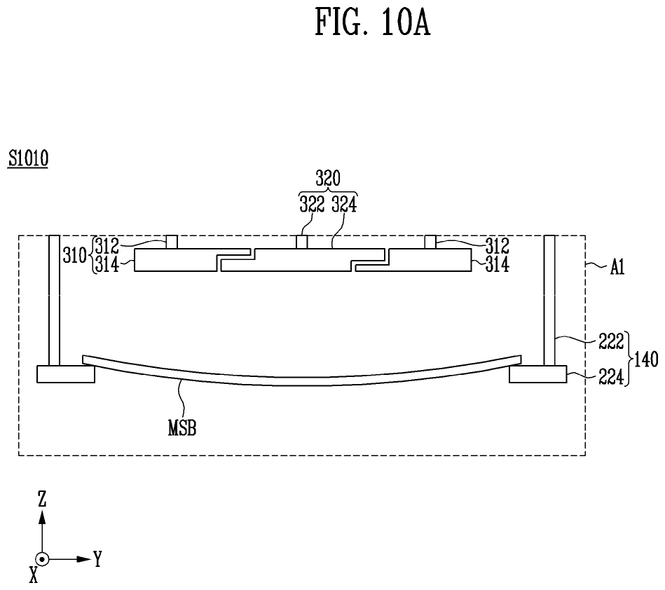

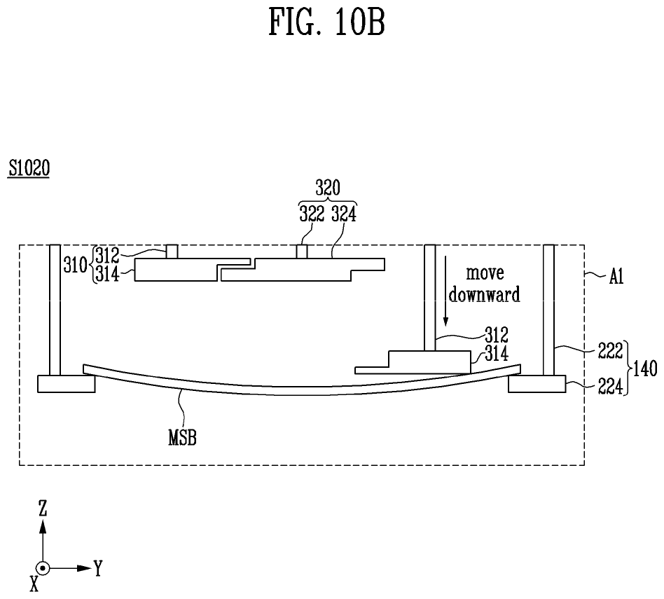

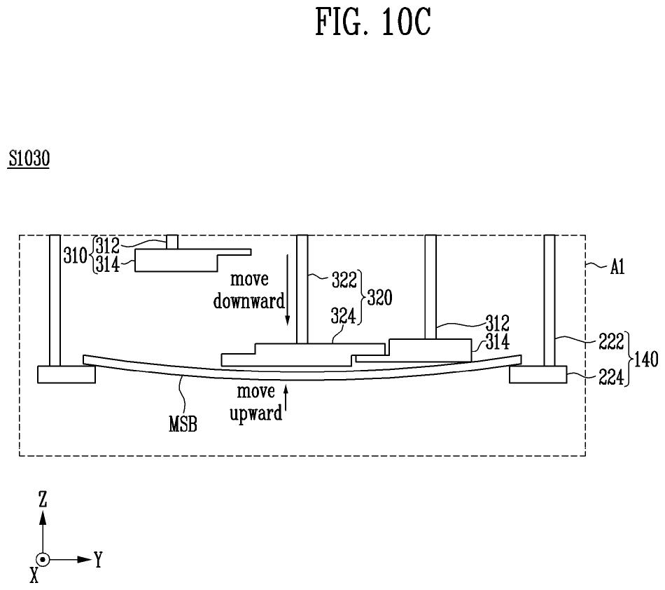

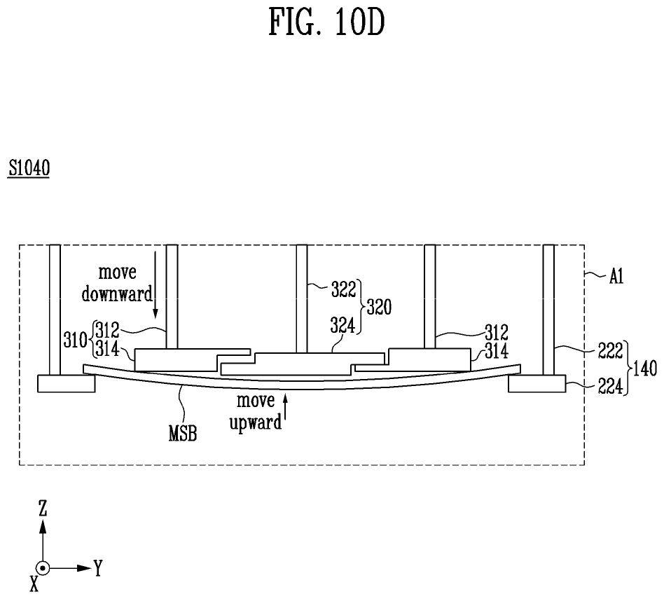

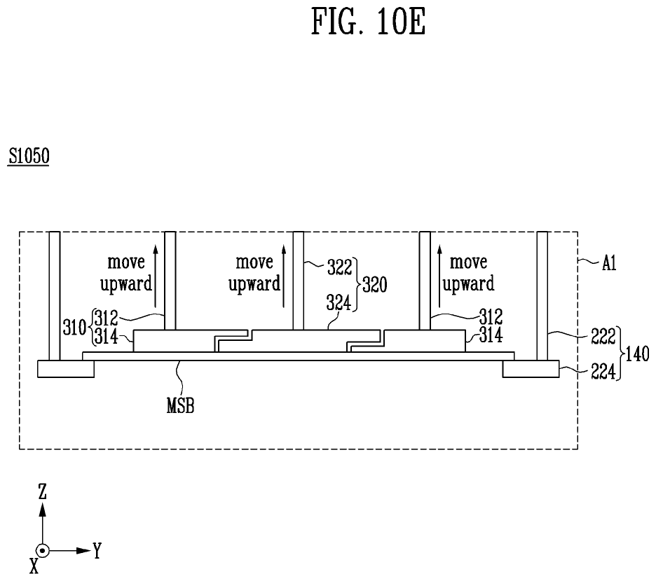

FIGS. 10A to 10E are diagrams for explaining one or more embodiments of a method of operating the substrate planarization device 800 shown in FIG. 8.

Referring to FIGS. 10A to 10E, a method of operating the substrate planarization device according to embodiments of the present disclosure may include seating a substrate (S1010), primarily lowering a peripheral coupler (S1020), lowering a central coupler (S1030), secondarily lowering the peripheral coupler (S1040), and raising the central coupler and the peripheral coupler (S1050).

FIG. 10A shows the seating the substrate (S1010). In the seating the substrate (S1010), the substrate MSB may be seated on the first support 140. The peripheral coupler 310 and the central coupler 320 may be in a raised state.

FIG. 10B shows the primarily lowering the peripheral coupler (S1020). In the primarily lowering the peripheral coupler (S1020), the peripheral coupler 310 may be lowered. In the operation (S1020), the lowered peripheral coupler 310 may correspond to the second peripheral coupler 310b described above (refer to FIG. 8). The central coupler 320 may be in a raised state.

FIG. 10C shows the lowering the central coupler (S1030). In the lowering the central coupler (S1030), the central coupler 320 may be lowered. The central coupler 320 may be lowered while pressing the peripheral coupler 310 in an area overlapping with the peripheral coupler 310. In the operation (S1030), the central coupler 320 may be lowered by a greater distance than the lowered distance of the peripheral coupler 310 in the primarily lowering the peripheral coupler (S1020) described above.

In the operation (S1030), the first electrostatic chuck 314 and the second electrostatic chuck 324 may generate the magnetic force. The substrate MSB may be attached to the peripheral coupler 310 and the central coupler 320 and raised. Thereby, the substrate MSB may be planarized compared to the previous operation.

FIG. 10D shows the secondarily lowering the peripheral coupler (S1040). In the secondarily lowering the peripheral coupler (S1040), the peripheral coupler 310 may be lowered. In the operation (S1040), the lowered peripheral coupler 310 may correspond to the first peripheral coupler 310a described above (refer to FIG. 8). In the operation (S1040), the peripheral coupler 310 may be lowered by a distance that is less than the lowered distance of the peripheral coupler 310 in the primarily lowering the peripheral coupler (S1020) described above (refer to FIG. 10B). In the operation (S1020), the first electrostatic chuck 314 and the second electrostatic chuck 324 may generate the magnetic force.

FIG. 10E shows the raising the central coupler and the peripheral coupler (S1050). In the operation (S1050), the first electrostatic chuck 314 and the second electrostatic chuck 324 may generate the magnetic force. The substrate MSB may be attached to the peripheral coupler 310 and the central coupler 320 and raised. In the operation (S1050), the central coupler 320 may be raised by a greater distance than the peripheral coupler 310. In the operation (S1050), the substrate MSB may be planarized. For example, the degree of deflection of the substrate may converge to 0 or a value close thereto.

A deposition material may be deposited on the substrate MSB planarized according to the method of operating the substrate planarization device.

As described with reference to FIGS. 1 to 10E, according to the substrate planarization device 160, the deposition system 100 including the same, and the method of operating the substrate planarization device according to the embodiments of the present disclosure, the substrate MSB can be stably planarized, and the deposition quality can be improved.

According to the substrate planarization device, the deposition system including the same, and the method of operating the substrate planarization device according to the embodiments of the present disclosure, a substrate can be planarized.

The drawings referred to heretofore and the detailed description of embodiments described above are merely illustrative of the present disclosure. It is to be understood that the embodiments have been disclosed for illustrative purposes only, and are not intended to limit the meaning or scope of the present disclosure as set forth in the claims. Therefore, those skilled in the art will appreciate that various modifications and equivalent embodiments are possible without departing from the scope of the present disclosure. Accordingly, the true technical protection scope of the present disclosure should be determined by the technical idea of the appended claims, with functional equivalents thereof to be included therein.

What is claimed is:

1. A substrate planarization device comprising:
a peripheral coupler comprising a first electrostatic chuck configured to be attached to a peripheral area of a substrate, and a first elevator configured to raise and lower the first electrostatic chuck in a vertical direction within a first movable range; and
a central coupler comprising a second electrostatic chuck configured to be attached to a central area of the substrate, and a second elevator that is configured to raise and lower the second electrostatic chuck in the vertical direction within a second movable range that is greater than the first movable range.

2. The substrate planarization device of claim 1, wherein the first electrostatic chuck and the second electrostatic chuck are configured to be individually lowered.

3. The substrate planarization device of claim 2, wherein a lowered distance of the second electrostatic chuck is greater than a lowered distance of the first electrostatic chuck.

4. The substrate planarization device of claim 1, wherein the first electrostatic chuck at least partially surrounds the second electrostatic chuck.

5. The substrate planarization device of claim 1, wherein the peripheral coupler comprises a first peripheral coupler on one side of the central coupler, and a second peripheral coupler on another side of the central coupler,
wherein the first peripheral coupler comprises the first electrostatic chuck and the first elevator, and
wherein the second peripheral coupler comprises another first electrostatic chuck and another first elevator.

6. The substrate planarization device of claim 5, wherein the first peripheral coupler and the second peripheral coupler are spaced apart from each other with the central coupler interposed therebetween.

7. The substrate planarization device of claim 1, wherein the first electrostatic chuck and the second electrostatic chuck do not overlap each other in the vertical direction.

8. The substrate planarization device of claim 7, wherein the first electrostatic chuck and the second electrostatic chuck are spaced apart from each other.

9. The substrate planarization device of claim 1, wherein at least a portion of the first electrostatic chuck and at least a portion of the second electrostatic chuck overlap each other in the vertical direction.

10. The substrate planarization device of claim 9, wherein the first electrostatic chuck comprises a first protruding portion protruding toward the second electrostatic chuck,
wherein the second electrostatic chuck comprises a second protruding portion protruding toward the first electrostatic chuck,
wherein the first electrostatic chuck comprises a first recessed portion corresponding to the second protruding portion, and
wherein the second electrostatic chuck comprises a second recessed portion corresponding to the first protruding portion.

11. The substrate planarization device of claim 1, wherein the first protruding portion is on the first recessed portion, and
wherein the second recessed portion is on the second protruding portion.

12. The substrate planarization device of claim 10, wherein the first recessed portion is on the first protruding portion, and
wherein the second protruding portion is on the second recessed portion.

13. The substrate planarization device of claim 1, wherein a size of the first electrostatic chuck is less than a size of the second electrostatic chuck.

14. A deposition system comprising:
a chamber;
a deposition source inside the chamber, and configured to supply a deposition material into the chamber;
a support above the deposition source, and configured to support a substrate for receiving the deposition material; and
a substrate planarization device comprising a peripheral coupler configured to apply a magnetic force to a peripheral area of the substrate, and a central coupler configured to apply a magnetic force to a central area of the substrate.

15. The deposition system of claim 14, wherein the peripheral coupler comprises:
a first electrostatic chuck attached to the peripheral area of the substrate; and
a first elevator configured to raise and lower the first electrostatic chuck in a vertical direction within a first movable range, and
wherein the central coupler comprises:
a second electrostatic chuck attached to the central area of the substrate; and
a second elevator configured to raise and lower the second electrostatic chuck in the vertical direction within a second movable range that is greater than the first movable range.

16. The deposition system of claim 14, further comprising a mask assembly overlapping the substrate planarization device on the deposition source.

17. A method of operating a substrate planarization device comprising:
lowering a central coupler to a central area of a substrate;
lowering a peripheral coupler to a peripheral area of the substrate; and
planarizing the substrate by raising the central coupler by a greater distance than the peripheral coupler.

18. The method of claim 17, wherein the raising the central coupler occurs before the lowering the peripheral coupler.

19. The method of claim 18, wherein a distance at which the substrate sags in a direction of gravity is greater than about 0 mm and less than about 7 mm after the raising the central coupler.

20. The method of claim 17, wherein, in the lowering the central coupler, the central coupler presses the peripheral coupler.
